(19) United States
(12) Patent Application Publication
(10) Pub. No.: US 2007/0082273 A1
(43) Pub. Date: Apr. 12, 2007

(54) Photomask and image device manufacturing method

(76) Inventor: Yoshinori Iwanaga, Kumamoto-shi (JP)

Correspondence Address: SUGHRUE MION, PLLC, 2100 PENNSYLVANIA AVENUE, N.W., SUITE 800, WASHINGTON, DC, 20037, US

(21) Appl. No.: 10/577,915

(22) PCT Filed: Oct. 25, 2004
(86) PCT No.: PCT/JP04/16177

§ 371 Date: May 1, 2006

(30) Foreign Application Priority Data
Oct. 30, 2003 (JP) 2003-370938

(51) Int. Cl. G21K 5/00; G03C 5/00; G03F 1/00

(52) U.S. Cl. 430/5; 378/35; 430/322

(57) ABSTRACT

In a photomask formed with a device pattern made of a light-shielding film pattern in a transfer area on a front surface of an optically transparent substrate, the photomask includes a non-device pattern such as a product identification pattern composed of a light-shielding film pattern in a non-transfer area at a peripheral portion, wherein there is provided, at a back surface of the optically transparent substrate opposed to at least a position where the non-device pattern is formed, a light-transmission reducing thin film as light-transmission reducing means for reducing transmission of exposure light entering from the peripheral portion of the back surface of the optically transparent substrate.

### TECHNICAL FIELD

This invention relates to a photomask for use in pattern transfer and an image device manufacturing method using the photomask.

### BACKGROUND ART

Conventionally, the manufacturing processes of a semiconductor device, an image device such as an imaging device or a display device, or the like include the process of irradiating exposure light through a photomask so as to transfer a pattern to a photosensitive material on a device substrate by the use of an exposure system such as a reduction-projection exposure system. The photomask used in this event generally has a light-shielding film pattern on a rectangular optically transparent substrate of glass or the like. The light-shielding film pattern is mainly made of chromium, molybdenum silicide, or the like.

Normally, in the foregoing exposure system, transfer of a pattern is carried out by disposing a photomask so that its front surface (light-shielding film pattern surface) faces downward, and irradiating exposure light from the back surface (glass surface) of the photomask. Therefore, if the reflectance of the front surface of the photomask is high, stray light is problematically generated due to multiple reflection between a transfer target surface and the photomask to thereby reduce imaging characteristics. Consequently, the surface of the light-shielding film is controlled at low reflection. For example, in the case of a photomask with chromium as a main component, since the reflectance of a chromium film is as high as about 40 to 50% around exposure light (200 nm to 500 nm), a chromium oxide based reflection preventing film is formed thereon to thereby suppress the reflectance to about 15%. It is noted here that the reflectance of the glass surface is about 8%. Further, there is also a double-sided reflection preventing type photomask formed with a reflection preventing film also on the substrate side in order to reduce multiple reflection between the back surface of the photomask and an illumination system.

Generally, a photomask has a transfer area provided at its center portion and formed with a pattern to be transferred onto a transfer target, and a non-transfer area provided at its peripheral portion. In the non-transfer area at the peripheral portion, for example, a product name of the photomask for identification by human eyes or a light-shielding film pattern indicative of product identification information such as a bar code for identifying the photomask according to a photomask identification method as described, for example, in Japanese Unexamined Patent Application Publication (JP-A) No. 2000-99619 is formed. Then, when pattern transfer is performed by the use of such a photomask, use is made of a blind that shields exposure light so as to prevent irradiation of the exposure light onto the non-transfer area. As this blind, there is one that is disposed right above the back surface of the photomask or an imaging type blind that forms a real image in the same plane as the pattern of the photomask.

### DISCLOSURE OF THE INVENTION

However, although the blind is provided in the exposure system, the non-device pattern such as the foregoing light-shielding film pattern indicative of the product identification information formed in the non-transfer area at the peripheral portion of the photomask is problematically resolved on the transfer target surface due to the influence of stray light in the exposure system.

Further, upon manufacturing an image device such as an imaging element or a display device, since a simple repeating pattern like a pixel pattern is transferred, an unnecessary image of the non-device pattern is resolved. As a result, a problem particularly arises because there is a possibility that an error in pattern line width of the pixel pattern agrees with a tendency of the shape of the non-device pattern so that unevenness in the shape of the non-device pattern is generated in an image.

This invention has been made in view of the foregoing problems and has an object to provide a photomask that can prevent a non-device pattern formed in a non-transfer area of the photomask from being resolved on a transfer target surface.

Further, this invention has an object to provide a method of manufacturing an image device that can prevent unevenness in the shape of the non-device pattern of the photomask from being generated in an image.

For achieving the foregoing object, this invention has the following structures.

(Structure 1) A photomask formed with a light-shielding film pattern on a front surface of an optically transparent substrate, wherein:

the photomask comprises a non-device pattern composed of a light-shielding film pattern in a non-transfer area at a peripheral portion,

wherein there is provided, at a back surface of the optically transparent substrate opposed to at least a position where the non-device pattern is formed, light-transmission reducing means for reducing transmission of exposure light entering from the peripheral portion of the back surface of the optically transparent substrate.

(Structure 2) A photomask according to the structure 1, wherein:

the light-transmission reducing means comprises a thin film or a coat having a function of reducing the transmission of the exposure light.

(Structure 3) A photomask according to the structure 1, wherein:

the light-transmission reducing means is formed by a surface roughening treatment of the surface of the substrate.

(Structure 4) A photomask formed with a light-shielding film pattern on a front surface of an optically transparent substrate, wherein:

the photomask comprises a non-device pattern composed of a light-shielding film pattern in a non-transfer area at a peripheral portion,

wherein there is provided means for reducing a difference in reflectance between a pattern portion and a non-pattern portion of the non-device pattern with respect to exposure light entering from a back surface of the optically transparent substrate, thereby preventing the non-device pattern from being resolved on a transfer target surface.

(Structure 5) A photomask according to the structure 4, wherein:

the reflectance of a light-shielding film of the pattern portion or the non-pattern portion of said non-device pattern with respect to the exposure light is adjusted so as to reduce the difference in reflectance between the pattern portion and the non-pattern portion with respect to the exposure light entering from the back surface of the optically transparent substrate.

(Structure 6) A photomask formed with a light-shielding film pattern on a front surface of an optically transparent substrate, wherein:

the photomask comprises a non-device pattern composed of a light-shielding film pattern in a non-transfer area at a peripheral portion,

wherein a pattern portion and a non-pattern portion of the non-device pattern are formed by a combination of light-shielding films such that the pattern portion and the non-pattern portion differ in reflectance with respect to exposure light entering from a front surface of the photomask, but no substantial difference in reflectance between the pattern portion and the non-pattern portion is generated with respect to exposure light entering from a back surface of the photomask.

(Structure 7) A photomask formed with a light-shielding film pattern on a front surface of an optically transparent substrate, wherein:

the photomask comprises a non-device pattern composed of a light-shielding film pattern in a non-transfer area at a peripheral portion,

wherein there is provided means for reducing a difference in reflectance between a pattern portion and a non-pattern portion of the non-device pattern with respect to exposure light entering from a front surface of the photomask, thereby preventing the non-device pattern from being resolved on a transfer target surface.

(Structure 8) A photomask according to the structure 7, wherein:

the reflectance of a light-shielding film of the pattern portion or the non-pattern portion of the non-device pattern with respect to the exposure light is adjusted so as to reduce the difference in reflectance between the pattern portion and the non-pattern portion with respect to the exposure light entering from the front surface of the photomask.

(Structure 9) A photomask formed with a light-shielding film pattern on a front surface of an optically transparent substrate, wherein:

the photomask comprises a non-device pattern composed of a light-shielding film pattern in a non-transfer area at a peripheral portion,

wherein a fine pattern, which is substantially incapable of being resolved on a transfer target surface, is formed on the non-device pattern or in an area where the non-device pattern is formed.

(Structure 10) An image device manufacturing method, comprising:

a step of performing pattern transfer by the use of the photomask according to any of structures 1 to 9.

Herein, use can be made, as the light-shielding film pattern of this invention, of a pattern mainly made of chromium, a pattern mainly made of molybdenum silicide, or the like. As the photomask, use is made of a photomask of a two-layer or multilayer structure having a reflection preventing film at its front surface, or a photomask of a double-sided reflection preventing type formed with a reflection preventing film also at its back surface.

As the foregoing optically transparent substrate, use can be made of a glass substrate made of a synthetic quartz glass or the like.

In this invention, the non-device pattern includes a product name or a product code of the photomask, a product identification pattern such a bar code for product identification, or various positioning marks such as alignment marks.

### BRIEF DESCRIPTION OF THE DRAWINGS

FIG. 1 shows diagrams illustrating a photomask according to Example 1 of this invention, wherein (a) is a plan view, (b) is a bottom view, and (c) is a sectional view.

FIG. 2 shows manufacturing process diagrams of the photomask according to Example 1 of this invention.

FIG. 3 is a sectional view of a photomask according to Example 5 of this invention.

FIG. 4 shows manufacturing process diagrams of the photomask according to Example 5 of this invention.

FIG. 5 is a sectional view of a photomask according to Example 6 of this invention.

FIG. 6 shows manufacturing process diagrams of the photomask according to Example 6 of this invention.

FIG. 7 shows diagrams illustrating a photomask according to Example 7 of this invention, wherein (a) is a plan view and (b) is a partial enlarged view.

FIG. 8 is an exemplary structural view of an exposure system.

### BEST MODE FOR CARRYING OUT THE INVENTION

Hereinbelow, the best mode of this invention will be described.

A photomask according to a first embodiment of this invention is a photomask formed with a light-shielding film pattern on a front surface of an optically transparent substrate and is characterized by comprising a non-device pattern composed of a light-shielding film pattern in a non-transfer area at a peripheral portion, wherein there is provided, at a back surface of the optically transparent substrate opposed to at least a position where the non-device pattern is formed, light-transmission reducing means for reducing transmission of exposure light entering from the peripheral portion of the back surface of the optically transparent substrate.

According to the foregoing structure, it is possible to reduce the entrance of the exposure light from the back surface at the peripheral portion of the photomask. Therefore, it can be prevented that the exposure light entering from the back surface at the peripheral portion of the photomask is reflected by the surface of the non-device pattern and its reflected light becomes stray light so that the non-device pattern is resolved on a transfer target surface.

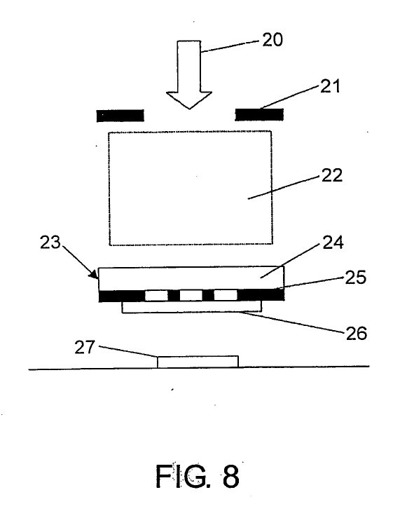

That is, for example, when use is made of an exposure system having an imaging type blind, since, as shown in FIG. 8, an optical system 22 is disposed between a photomask 23 and a blind 21, light entering from the back surface of the photomask 23 and reflected becomes stray light and reaches the photomask again. The stray light also reaches the peripheral portion of the substrate as oblique light. When it reaches a non-device pattern, it is considered that the light resolving the non-device pattern repeats reflection and reaches a transfer target surface of a transfer target 27 so as to be resolved on the transfer target surface. In view of this, light-transmission reducing means is provided at a position of the back surface of the photomask opposed to at least a position where the non-device pattern is formed, to thereby shield the light from the peripheral portion of the photomask. In this manner, since it is possible to prevent the light from reaching the non-device pattern, it can be prevented that the light resolving the non-device pattern becomes the stray light. FIG. 8 is an exemplary structural diagram of the exposure system, wherein 24 denotes a transparent substrate in the photomask, 25 a light-shielding film pattern in the photomask, and 26 a pellicle for protecting the front surface of the photomask.

Herein, the light-transmission reducing means is means having a function of reducing the transmission of exposure light normally entering from the back surface of an optically transparent substrate (the back surface of a photomask) and preferably transmits 80% or less of the light as compared with the normal case (the case where the light-transmission reducing means is not provided). By this light-transmission reducing means, since the exposure light is subjected to any one of absorption, reflection, and scattering, or two or more kinds of them, the transmission of the exposure light entering from the back surface at the peripheral portion of the photomask is reduced.

As the foregoing light-transmission reducing means, use is made of a thin film or a coat (including a sheet-like material) having the function of reducing the transmission of the exposure light, i.e. the function of absorbing, reflecting, or scattering the exposure light, or the function of two or more kinds of them, the surface of the substrate reformed (e.g. surface-roughened) by laser irradiation or the like, or the like having such a function. As the foregoing thin film, use is, for example, made of an applied film, a deposited film, a sputtered film. Further, as the material, any material may be used as long as it has the foregoing function and use is, for example, made of a metal, a metal compound such as a metal oxide, a nitride, a carbide, or a fluoride, a mixture of them, carbon, an organic resin, or the like.

In the foregoing first embodiment, when a plurality of kinds of non-device patterns among the foregoing non-device patterns are formed in a single photomask, the light-transmission reducing means may be provided with respect to all the non-device patterns or only the selected non-device pattern. Further, in the case where a problem arises with respect to part of a certain non-device pattern, the light-transmission reducing means may be provided with respect to the part of the non-device pattern.

Further, in the case of the foregoing first embodiment, it is, of course, possible to recognize the non-device pattern such as the product identification pattern from the front surface of the photomask.

Next, a photomask according to a second embodiment of this invention is a photomask formed with a light-shielding film pattern on a front surface of an optically transparent substrate and is characterized by comprising a non-device pattern composed of a light-shielding film pattern in a non-transfer area at a peripheral portion, wherein there is provided means for reducing a difference in reflectance between a pattern portion and a non-pattern portion of the non-device pattern with respect to exposure light entering from a back surface of the optically transparent substrate, thereby preventing the non-device pattern from being resolved on a transfer target surface.

According to the foregoing structure, even if exposure light directly enters from the back surface of the photomask or reflected light from the transfer target surface enters from the back surface at the peripheral portion of the photomask, and is then reflected, a difference in reflectance of such reflected light at the pattern portion and the non-pattern portion of the non-device pattern is reduced. Therefore, it is possible to reduce a possibility of resolution of the non-device pattern when the light reaches the transfer target surface.

Herein, the foregoing pattern portion and non-pattern portion of the non-device pattern are such that when the non-device pattern is formed by a void pattern of the light-shielding film pattern, the void pattern portion is defined as the pattern portion and its peripheral substrate portion as the non-pattern portion. On the other hand, when the non-device pattern is formed by a remaining pattern of the light-shielding film pattern, the remaining pattern portion is defined as the pattern portion and its peripheral substrate portion as the non-pattern portion.

In this second embodiment, by providing the means for reducing the difference in reflectance between the pattern portion and the non-pattern portion of the non-device pattern, the difference in reflectance between the pattern portion and the non-pattern portion is reduced as compared with a conventional photomask. It is preferable that the reflectance difference is 80% or less as compared with the conventional photomask. The conventional photomask comprises a photomask of a two-layer or multilayer structure having a reflection preventing film at its front surface, or a photomask of a double-sided reflection preventing type formed with a reflection preventing film also at its back surface. The problem of the resolution of the non-device pattern onto the transfer target surface differs in degree depending on the kind of exposure system and the kind of photomask. Therefore, when the problem arises, this invention can be adopted according to the kinds of exposure system and photomask.

Also in this second embodiment, when a plurality of kinds of non-device patterns among the foregoing non-device patterns are formed in a single photomask, the means for reducing the reflectance difference may be provided with respect to an area where all the non-device patterns are formed or only an area where the selected non-device pattern is formed. Further, in the case where a problem arises with respect to part of a certain non-device pattern, the means for reducing the reflectance difference may be provided with respect to an area of the part of the non-device pattern.

As such means for reducing the reflectance difference, the following method can be cited as an example.

That is, it is a method of adjusting a reflectance of a light-shielding film of the pattern portion or the non-pattern portion of the non-device pattern with respect to the exposure light so as to reduce the difference in reflectance between the pattern portion and the non-pattern portion with respect to the exposure light entering from the back surface of the optically transparent substrate. Specifically, it is a method of partially etching the light-shielding film of the pattern portion or the non-pattern portion in a thickness direction to provide transmissivity, thereby setting a film thickness that causes the reflectance of the non-pattern portion or the pattern portion to approach the reflectance of the optically transparent substrate. In the foregoing case, it is possible to recognize the non-device pattern such as the product identification pattern from the front or back surface of the photomask.

Next, a photomask according to a third embodiment of this invention is a photomask formed with a light-shielding film pattern on a front surface of an optically transparent substrate and is characterized by comprising a non-device pattern composed of a light-shielding film pattern in a non-transfer area at a peripheral portion, wherein a pattern portion and a non-pattern portion of the non-device pattern are formed by a combination of light-shielding films such that the pattern portion and the non-pattern portion differ in reflectance with respect to exposure light entering from a front surface of the photomask, but no substantial difference in reflectance between the pattern portion and the non-pattern portion is generated with respect to exposure light entering from a back surface of the photomask.

According to the foregoing structure, even if the exposure light entering from the back surface of the photomask is reflected by the non-device pattern surface, no substantial difference in reflectance is generated between the pattern portion and the non-pattern portion of the non-device pattern. Therefore, there is no possibility of resolution of the non-device pattern when the reflected light reaches the transfer target surface. The reflectance differs between the pattern portion and the non-pattern portion of the non-device pattern with respect to the exposure light entering from the front surface of the photomask. However, since the light entering from the back surface of the photomask is overwhelming in a normal photomask using method, the non-device pattern is difficult to be resolved on the transfer target surface in this embodiment. With respect to the exposure light entering from the front surface of the photomask, the difference in reflectance between the pattern portion and the non-pattern portion of the non-device pattern is preferably set to a degree that allows the non-device pattern such as the product identification pattern to be visually recognized from the front surface of the photomask.

Specifically, in the case of the photomask of this embodiment, etching of a light-shielding film is partially performed in a thickness direction upon forming the non-device pattern. In this manner, at the back surface, there is substantially no difference in reflectance between the pattern portion and the non-pattern portion so that the non-device pattern cannot be recognized as a pattern as compared with the case where the substrate is exposed like a void pattern. While at the front surface, a difference in reflectance is generated to a degree that allows the non-device pattern to be visually recognized. In the above case, it is possible to recognize the non-device pattern such as the product identification pattern from the front surface of the photomask.

Subsequently, a photomask according to a fourth embodiment of this invention is a photomask formed with a light-shielding film pattern on a front surface of an optically transparent substrate and is characterized by comprising a non-device pattern composed of a light-shielding film pattern in a non-transfer area at a peripheral portion, wherein there is provided means for reducing a difference in reflectance between a pattern portion and a non-pattern portion of the non-device pattern with respect to exposure light entering from a front surface of the photomask, thereby preventing the non-device pattern from being resolved on a transfer target surface.

According to the foregoing structure, even if reflected light from the transfer target surface is irradiated onto the peripheral portion of the front surface of the photomask and reflected, the difference in reflectance between the pattern portion and the non-pattern portion of the non-device pattern is reduced. Consequently, it is possible to reduce a possibility of resolution of the non-device pattern when the reflected light reaches the transfer target surface.

Herein, like in the foregoing second and third embodiments, the pattern portion and non-pattern portion of the non-device pattern are such that when the non-device pattern is formed by a void pattern of the light-shielding film pattern, the void pattern portion is defined as the pattern portion and its peripheral substrate portion as the non-pattern portion. While, when the non-device pattern is formed by a remaining pattern of the light-shielding film pattern, the remaining pattern portion is defined as the pattern portion and its peripheral substrate portion as the non-pattern portion.

In this fourth embodiment, there is provided the means for reducing the difference in reflectance between the pattern portion and the non-pattern portion of the non-device pattern with respect to the exposure light entering from the front surface of the photomask. With this structure, the difference in reflectance between the pattern portion and the non-pattern portion of the non-device pattern is reduced as compared with a conventional photomask. It is preferable that the reflectance difference is 80% or less as compared with the conventional photomask. Like in the foregoing embodiments, the conventional photomask comprises a photomask of a two-layer or multilayer structure having a reflection preventing film at its front surface, or a photomask of a double-sided reflection preventing type formed with a reflection preventing film also at its back surface. The problem of the resolution of the non-device pattern onto the transfer target surface differs in degree depending on the kind of exposure system and the kind of photomask. Therefore, when the problem arises, this invention can be adopted according to the kinds of exposure system and photomask.

Also in this fourth embodiment, when a plurality of kinds of non-device patterns among the foregoing non-device patterns are formed in a single photomask, the means for reducing the reflectance difference may be provided with respect to an area where all the non-device patterns are formed or only an area where the selected non-device pattern is formed. Further, in the case where a problem arises with respect to part of a certain non-device pattern, the means for reducing the reflectance difference may be provided with respect to an area of the part of the non-device pattern.

As the means for reducing the reflectance difference in this embodiment, the following method can be cited as an example.

That is, it is a method of adjusting a reflectance of a light-shielding film of the pattern portion or the non-pattern portion of the non-device pattern with respect to the exposure light so as to reduce the difference in reflectance between the pattern portion and the non-pattern portion with respect to the exposure light entering from the front surface of the photomask. Specifically, like in the foregoing second embodiment, it is a method of partially etching the light-shielding film of the pattern portion or the non-pattern portion in a thickness direction to provide transmissivity, thereby setting a film thickness that causes the reflectance of the non-pattern portion or the pattern portion to approach the reflectance of the optically transparent substrate. In the foregoing case, it is possible to recognize the non-device pattern such as the product identification pattern from the front or back surface of the photomask.

Further, a photomask according to a fifth embodiment of this invention is a photomask formed with a light-shielding film pattern on a front surface of an optically transparent substrate and is characterized by comprising a non-device pattern composed of a light-shielding film pattern in a non-transfer area at a peripheral portion, wherein a fine pattern, which is substantially incapable of being resolved on a transfer target surface, is formed on the non-device pattern or in an area where the non-device pattern is formed.

According to the foregoing structure, by the use of the fine pattern which is formed on the non-device pattern or in the area where the non-device pattern is formed and which is substantially incapable of being resolved on the transfer target surface (e.g. less than the resolution limit by the exposure light), the transmissivity or reflectance of the non-device pattern can be reduced as compared with a conventional photomask formed with no such a fine pattern. Further, even if reflected light generated at the non-device pattern portion reaches the transfer target surface, the fine pattern is not substantially resolved on the transfer target surface. It is therefore possible to prevent the non-device pattern overlapped with the fine pattern from being resolved on the transfer target surface.

Specifically, when a pattern portion of the non-device pattern is a void pattern of the light-shielding film, the fine pattern is formed on the non-device pattern or on the non-device pattern and in its peripheral area. On the other hand, when the non-device pattern is a remaining pattern of the light-shielding film, it is considered that the remaining pattern is etched into the shape of the fine pattern.

The shape of the fine pattern can be properly selected such as a slit shape or a mesh shape and the size thereof is properly determined according to required transmission characteristics or reflection characteristics within such a size range that can substantially prevent resolution on the transfer target surface.

The photomask of this invention can be suitably used in the manufacture of an image device having a process of performing pattern transfer by the use of a photomask. As the image device, use is specifically made of an imaging device such as a solid imaging device like a CCD, a CMOS, a VMIS, or the like, or a display device such as a liquid crystal display device, a plasma display device, an EL display device, a LED display device, or a DMD display device.

Hereinbelow, this invention will be described in further detail by the use of examples.

### EXAMPLE 1

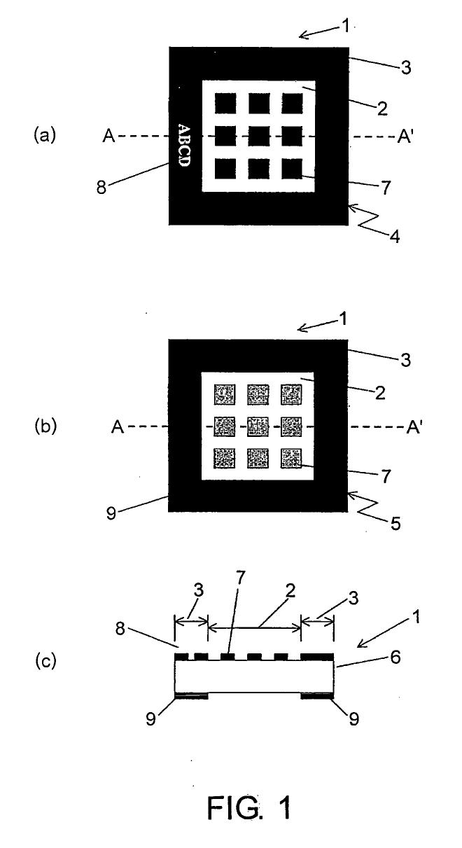

FIG. 1 shows a photomask according to Example 1. FIG. 1, (a) is a plan view when the photomask of this example is oriented horizontally, FIG. 1, (b) is a diagram as seen from the back surface of the photomask of Example 1, and FIG. 1, (c) is a sectional view of a portion identified by a broken line A-A′ in FIG. 1, (a) and FIG. 1, (b).

As shown in FIG. 1, the photomask 1 of this example has a transfer area 2 and a non-transfer area 3 at its peripheral portion. On a front surface 4 of the photomask, a device pattern 7 composed of a light-shielding film pattern is formed in the transfer area 2 of the front surface of a transparent substrate 6 made of a synthetic quartz glass or the like. The non-transfer area 3 of the front surface of the transparent substrate 6 has a product identification pattern 8 as a non-device pattern formed in a light-shielding film by a void pattern. Further, on a back surface 5 of the photomask corresponding to the non-transfer area 3, a light-transmission reducing thin film 9 as light-transmission reducing means is formed by inkjet printing by the use of a reflection preventing paint made of, for example, MEK (methyl ethyl ketone) and particles of zinc oxide (ZnO).

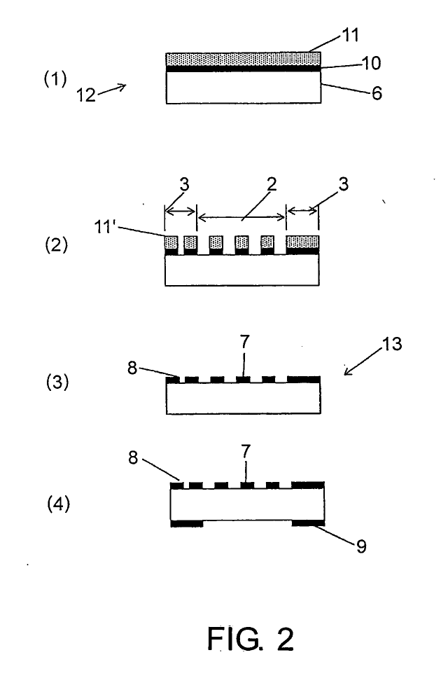

Next, a manufacturing method of the photomask 1 of this example will be described with reference to manufacturing process diagrams of FIG. 2.

A light-shielding film 10 having a chromium film and a chromium oxide film formed in turn is formed on a transparent substrate 6 and a resist film 11 is applied thereon. In this manner, a photomask blank 12 with a resist film is prepared (see FIG. 2, (1)).

Then, a device pattern and a product identification pattern are written in a transfer area and a non-transfer area, respectively, on the resist film 11 and developed to thereby form a resist pattern 11′. Then, the light-shielding film 10 is etched along the resist pattern 11′ (see FIG. 2, (2)).

Successively, the resist pattern is stripped or removed and cleaning is carried out. Thus, a photomask 13 before formation of light-transmission reducing means, having a device pattern 7 and a product identification pattern 8 formed on the front surface of the transparent substrate 6 is obtained (see FIG. 2, (3)).

Subsequently, by the use of an inkjet printer capable of non-contact printing, the foregoing reflection preventing paint is applied to the back surface of the photomask at a portion corresponding to the non-transfer area 3 and then dried (see FIG. 2, (4)).

The light-transmission reducing thin film 9 thus formed has a transmissivity of 5% or less with respect to exposure light (wavelength 230 to 370 nm).

By performing pattern transfer onto a transfer target surface by the use of the photomask 1 of this example, exposure light irradiated from the back surface of the photomask can be prevented from reaching the non-device pattern formed in the non-transfer area at the peripheral portion of the photomask.

### EXAMPLE 2

In Example 2, a reflection preventing film made of, for example, polyester is bonded to the back surface of a transparent substrate corresponding to a non-transfer area of a photomask by the use of an adhesive. In this manner, a light-shielding film is formed.

A manufacturing method of a photomask of this example will be described hereinbelow.

Like in Example 1, a photomask before formation of a light-shielding film, having a device pattern and a product identification pattern formed on the front surface of a transparent substrate, is obtained.

Then, the foregoing reflection preventing film (thickness 50 μm) with a portion corresponding to a transfer area having been cut out in advance is bonded to the back surface of the photomask by the use of an adhesive. Thus, a light-shielding film id formed in a non-transfer area of the back surface of the transparent substrate.

The light-shielding film thus formed has a transmissivity of 2% or less with respect to exposure light (wavelength 230 to 370 nm).

By performing pattern transfer by the use of the photomask of this example, exposure light irradiated from the back surface of the photomask can be prevented from reaching the non-device pattern formed in the non-transfer area at the peripheral portion of the photomask.

### EXAMPLE 3

In Example 3, a low-reflection film made of, for example, a chromium oxide is formed by deposition, as a light-shielding film, on the back surface of a transparent substrate corresponding to a non-transfer area of a photomask.

A manufacturing method of a photomask of this example will be described hereinbelow.

Like in Example 1, a photomask before formation of a light-shielding film, having a device pattern and a product identification pattern formed on the front surface of a transparent substrate, is obtained.

Then, a chromium oxide is deposited on the whole back surface of the photomask and a resist film is applied thereon. Next, the whole area corresponding to a transfer area is written on the resist film and then developed to thereby form a resist pattern. Successively, the chromium oxide film of the transfer area is etched along the resist pattern. Then, the resist pattern is stripped or removed and cleaning is carried out. In this manner, a light-shielding film is formed in a non-transfer area of the back surface of the transparent substrate.

The light-shielding film thus formed has a reflectance of 12% or less with respect to exposure light (wavelength 230 to 370 nm).

By performing pattern transfer by the use of the photomask of this example, exposure light irradiated from the back surface of the photomask can be prevented from reaching the non-device pattern formed in the non-transfer area at the peripheral portion of the photomask.

### EXAMPLE 4

In Example 4, by applying laser irradiation onto the back surface of a transparent substrate corresponding to a non-transfer area of a photomask, the processing for obtaining a function of scattering light is carried out. In this manner, light-transmission reducing means is formed.

A manufacturing method of a photomask of this example will be described hereinbelow.

Like in Example 1, a photomask having a device pattern and a product identification pattern formed on the front surface of a transparent substrate is obtained.

Then, a carbon dioxide laser is used to roughen the glass surface in a non-transfer area of the back surface of the photomask. Thus, the processing for scattering exposure light is carried out.

The processed surface, thus formed, of the non-transfer area has a transmissivity of 30% or less with respect to exposure light (wavelength 230 to 370 nm).

By performing pattern transfer by the use of the photomask of this example, light irradiated from the back surface of the photomask can be prevented from reaching the non-device pattern formed in the non-transfer area at the peripheral portion of the photomask.

### EXAMPLE 5

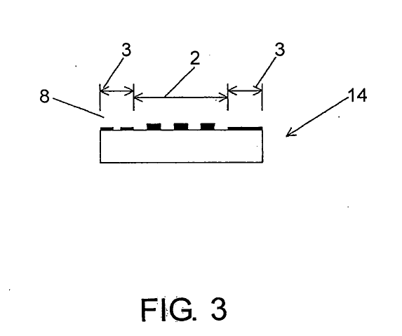

FIG. 3 is a sectional view of a photomask according to Example 5. In the photomask 14 of this example, the whole surface of a light-shielding film in a non-transfer area 3 at the peripheral portion of the photomask is partially etched in a thickness direction so as to have transmissivity and to be set to a thickness that causes its reflectance to be substantially the same as the reflectance of a substrate.

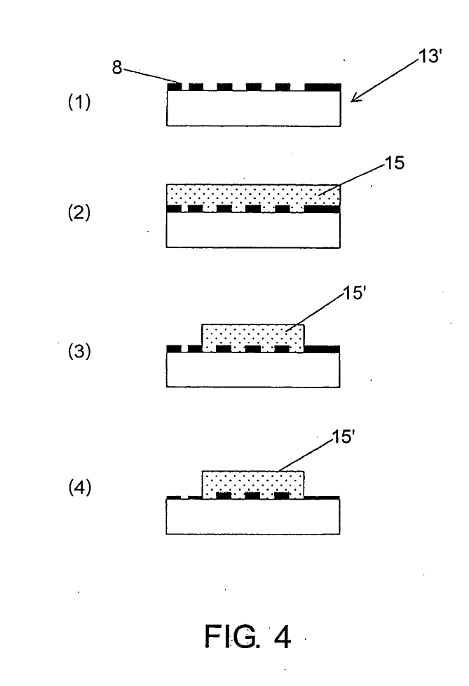

A manufacturing method of the photomask of this example will be described with reference to manufacturing process diagrams of FIG. 4.

At first, a photomask 13′ which is the same as the photomask of Example 1 before the formation of the light-transmission reducing means is obtained (see FIG. 4, (1)).

Then, a resist film 15 is applied to the front surface of the photomask 13′ (see FIG. 4, (2)), then exposure is performed so as to form a resist pattern that covers only a transfer area 2, and successively, development is carried out to form a resist pattern 15′ (see FIG. 4, (3)).

Then, the exposed light-shielding film in the non-transfer area 3 is partially etched in a thickness direction by the use of an etching liquid (see FIG. 4, (4)). Thereafter, the resist pattern is stripped or removed and cleaning is carried out. In this manner, the photomask 14 of this embodiment is obtained.

The reflectance of the thus formed light-shielding film of the non-transfer area 3 with respect to exposure light entering from the back surface is 15% which is a value close to about 8% of the substrate.

In this embodiment, the reflectance of the light-shielding film of the non-transfer area 3 with respect to exposure light irradiated from the front surface is also 15%.

By performing pattern transfer by the use of the photomask of this example, even if the exposure light irradiated from the back surface and the front surface of the photomask is reflected on the non-device pattern, a difference in reflectance between the pattern portion and the non-pattern portion of the non-device pattern is reduced. It is therefore possible to prevent the non-device pattern from being resolved on the transfer target surface.

### EXAMPLE 6

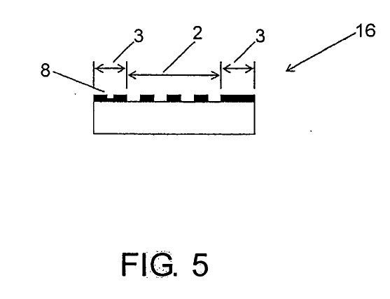

FIG. 5 is a sectional view of a photomask according to Example 6. The photomask 16 of this example is formed by partially etching a pattern portion of the product identification pattern 8 in a thickness direction upon forming a product identification pattern 8. As a consequence, at the back surface, there is substantially no difference in reflectance between the pattern portion and the non-pattern portion so that the non-device pattern cannot be recognized as a pattern as compared with the case where the substrate is exposed like a void pattern, while, at the front surface, a difference in reflectance is generated to a degree that allows the non-device pattern to be visually recognized.

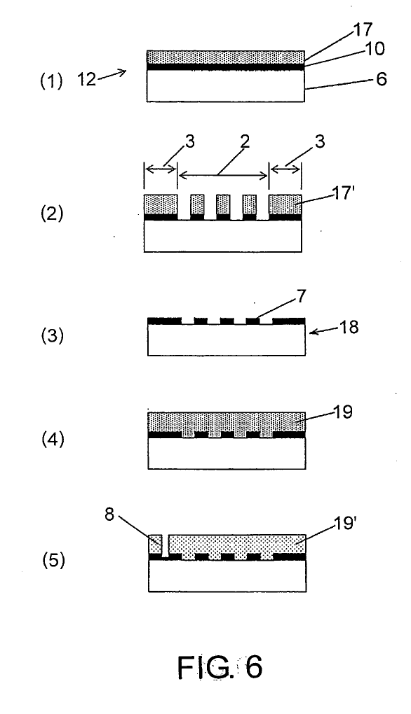

A manufacturing method of the photomask 16 of this example will be described with reference to manufacturing process diagrams of FIG. 6.

A light-shielding film 10 having a chromium film and a chromium oxide film formed in turn is formed on a transparent substrate 6 and a resist film 17 is applied thereon. In this manner, a photomask blank 12 with a resist film is prepared (see FIG. 6, (1)).

Then, a device pattern 7 in a transfer area is written on the resist film 17 and then developed to thereby form a resist pattern 17′, and successively, the light-shielding film 10 is etched along the resist pattern 17′ (see FIG. 6, (2)).

Subsequently, the resist pattern is stripped or removed and cleaning is carried out. Thus, a photomask 18 formed with the device pattern 7 but before formation of a product identification pattern is obtained (see FIG. 6, (3)).

Next, a resist film 19 is applied to the front surface of the photomask 18 (see FIG. 6, (4)), and then exposure is performed so as to form a resist pattern that exposes only a pattern portion of the product identification pattern. Successively, development is carried out to form a resist pattern 19′ (see FIG. 6, (5)).

Then, the light-shielding film of the exposed pattern portion in the non-transfer area 3 is partially etched in a thickness direction by the use of an etching liquid (e.g. the light-shielding film having a thickness of 1000 Å is partially etched in the thickness direction by 400 Å along the resist pattern) (see FIG. 6, (5)).

Finally, the resist pattern is stripped or removed and cleaning is carried out. In this manner, the photomask 16 of this embodiment is obtained.

The product identification pattern 8 thus formed cannot be recognized as a pattern from the back surface of the photomask.

Therefore, by performing pattern transfer by the use of the photomask 16 of this example, even if exposure light irradiated from the back surface of the photomask is reflected on the product identification pattern 8, there is no possibility of resolution as a pattern.

### EXAMPLE 7

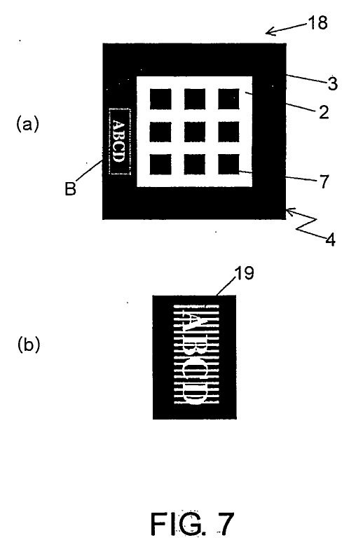

FIG. 7 (a) is a plan view of a photomask according to Example 7 and FIG. 7 (b) is a partial enlarged view of an area surrounded by a dotted line B shown in FIG. 7, (a).

In the photomask 18 of this example, a fine pattern 19, which is less than a resolution limit by exposure light, is formed on a product identification pattern 8 in a non-transfer area 3 at the peripheral portion of the photomask.

In the photomask 18 of this example, upon writing the product identification pattern, the fine pattern less than the resolution limit by the exposure light is also written so that it is possible to form the product identification pattern formed with the fine pattern.

The product identification pattern formed with the fine pattern in an overlapping manner as described above is difficult to be resolved as a pattern with respect to the exposure light irradiated from either the front surface or the back surface.

Therefore, by performing pattern transfer by the use of the photomask of this example, even if the exposure light irradiated from the back surface and the front surface of the photomask is reflected on the product identification pattern, it is possible to prevent resolution on the transfer target surface as the product identification pattern.

### INDUSTRIAL APPLICABILITY

This invention can prevent a non-device pattern such as a product identification pattern formed in a non-transfer area at the peripheral portion of a photomask from being resolved on a transfer target. As a consequence, this invention is applicable to a photomask that can realize highly accurate pattern transfer.

Further, this invention can prevent a non-device pattern such as a product identification pattern formed in a non-transfer area at the peripheral portion of a photomask for use in manufacturing an image device from being resolved on a transfer target. As a result, this invention is applicable to a manufacturing method of an image device that can prevent unevenness in the shape of the non-device pattern from being generated in an image.

1. A photomask formed with a light-shielding film pattern on a front surface of an optically transparent substrate, wherein:
the photomask comprises a non-device pattern composed of a light-shielding film pattern in a non-transfer area at a peripheral portion,
wherein there is provided, at a back surface of the optically transparent substrate opposed to at least a position where the non-device pattern is formed, light-transmission reducing means for reducing transmission of exposure light entering from the peripheral portion of the back surface of the optically transparent substrate.

2. A photomask according to claim 1, wherein:
the light-transmission reducing means comprises a thin film or a coat having a function of reducing the transmission of the exposure light.

3. A photomask according to claim 1, wherein:
the light-transmission reducing means is formed by a surface roughening treatment of the surface of the substrate.

4. A photomask formed with a light-shielding film pattern on a front surface of an optically transparent substrate, wherein:
the photomask comprises a non-device pattern composed of a light-shielding film pattern in a non-transfer area at a peripheral portion,
wherein there is provided means for reducing a difference in reflectance between a pattern portion and a non-pattern portion of the non-device pattern with respect to exposure light entering from a back surface of the optically transparent substrate, thereby preventing the non-device pattern from being resolved on a transfer target surface.

5. A photomask according to claim 4, wherein:
the reflectance of a light-shielding film of the pattern portion or the non-pattern portion of said non-device pattern with respect to the exposure light is adjusted so as to reduce the difference in reflectance between the pattern portion and the non-pattern portion with respect to the exposure light entering from the back surface of the optically transparent substrate.

6. A photomask formed with a light-shielding film pattern on a front surface of an optically transparent substrate, wherein:
the photomask comprises a non-device pattern composed of a light-shielding film pattern in a non-transfer area at a peripheral portion,
wherein a pattern portion and a non-pattern portion of the non-device pattern are formed by a combination of light-shielding films such that the pattern portion and the non-pattern portion differ in reflectance with respect to exposure light entering from a front surface of the photomask, but no substantial difference in reflectance between the pattern portion and the non-pattern portion is generated with respect to exposure light entering from a back surface of the photomask.

7. A photomask formed with a light-shielding film pattern on a front surface of an optically transparent substrate, wherein:
the photomask comprises a non-device pattern composed of a light-shielding film pattern in a non-transfer area at a peripheral portion,
wherein there is provided means for reducing a difference in reflectance between a pattern portion and a non-pattern portion of the non-device pattern with respect to exposure light entering from a front surface of the photomask, thereby preventing the non-device pattern from being resolved on a transfer target surface.

8. A photomask according to claim 7, wherein:
the reflectance of a light-shielding film of the pattern portion or the non-pattern portion of the non-device pattern with respect to the exposure light is adjusted so as to reduce the difference in reflectance between the pattern portion and the non-pattern portion with respect to the exposure light entering from the front surface of the photomask.

9. A photomask formed with a light-shielding film pattern on a front surface of an optically transparent substrate, wherein:
the photomask comprises a non-device pattern composed of a light-shielding film pattern in a non-transfer area at a peripheral portion,
wherein a fine pattern, which is substantially incapable of being resolved on a transfer target surface, is formed on the non-device pattern or in an area where the non-device pattern is formed.

10. An image device manufacturing method, comprising:
a step of performing pattern transfer by the use of the photomask according to claim 1.

11. An image device manufacturing method, comprising:
a step of performing pattern transfer by the use of the photomask according to claim 4.

12. An image device manufacturing method, comprising:
a step of performing pattern transfer by the use of the photomask according to claim 6.

13. An image device manufacturing method, comprising:
a step of performing pattern transfer by the use of the photomask according to claim 7.

14. An image device manufacturing method, comprising:
a step of performing pattern transfer by the use of the photomask according to claim 9.
